(19) United States
(12) Patent Application Publication
(10) Pub. No.: US 2025/0364068 A1
(43) Pub. Date: Nov. 27, 2025

(54) RANDOMIZED DATA POLARITY INVERSION OF COMPUTATIONAL WEIGHT DATA IN A DIGITAL IN-MEMORY COMPUTATION PROCESSING SYSTEM

(71) Applicant: STMicroelectronics International N.V., Geneva (CH)

(72) Inventors: Harsh RAWAT, Faridabad (IN); Nitin CHAWLA, Noida (IN); Manuj AYODHYAWASI, Noida (IN)

(73) Assignee: STMicroelectronics International N.V., Geneva (CH)

(21) Appl. No.: 19/201,379

(22) Filed: May 7, 2025

Related U.S. Application Data
(60) Provisional application No. 63/650,115, filed on May 21, 2024.

(51) Int. Cl. G11C 27/00

(52) U.S. Cl. CPC G11C 27/00

(57) ABSTRACT

Computational weight data for an in-memory computation operation is written to memory cells in a memory array with a randomly selected polarity inversion. During execution of the in-memory computation operation, the computational weight data is read from memory cells in the memory array. A polarity inversion is applied to the read computational weight data when that read computational weight data was written to memory cells in the memory array with the randomly selected polarity inversion.

### CROSS REFERENCE TO RELATED APPLICATIONS

This application claims the priority benefit of United States Provisional Application for Patent No. 63/650,115, filed May 21, 2024, the contents of which are incorporated herein by reference.

### TECHNICAL FIELD

Embodiments herein relate to the storage of computational weight data in the memory array of an in-memory computation processing system and, in particular, to the use of a randomized inversion of data polarity for computational weight data storage.

### BACKGROUND

An in-memory computation (IMC) processing system stores information in the bit cells of a memory array and performs calculations at the bit cell level. A n example of a calculation performed by an IMC processing system is a multiply and accumulate (MAC) operation where an input array of numbers (referred to as the feature or coefficient data) are multiplied by an array of computational weights stored in the memory and the products are added together to produce an output array of numbers.

By performing these calculations at the bit cell level in the memory, the IMC processing system does not need to move data back and forth between a memory device and a computing device. Thus, the limitations associated with data transfer bandwidth between devices are obviated and the computation can be performed with lower power consumption.

An IMC processing system includes a circuit that utilizes a memory array formed by a plurality of memory cells arranged in a matrix format. Each memory cell is programmed to store a bit of the computational weight data (also referred to as kernel data) for an in-memory compute operation. In an implementation, each bit of the computational weight data has either a logic “1” value or a logic “0” value which is represented, for example, by a logic state programmed into the memory cell.

It is often the case that the computational weight data is highly valuable and proprietary information. Persons of bad intent often try to extract the computational weight data using an extraction technique known in the art as a side channel attack which evaluates power consumption during operation of the IMC processing system. It is recognized that in neural processing applications utilizing in-memory computation, a mostly stationary approach to computational weight data storage is implemented, and because of this the stored computational weight data is static over prolonged periods of time during operation. This makes the stored computational weight data more susceptible to side channel attack extraction. There is a need in the art to provide the IMC processing system with protections against side channel attack efforts to decode the details of the computational weight data stored in the memory array.

### SUMMARY

In an embodiment, a circuit comprises: a memory array including a plurality of memory cells arranged in a matrix with plural rows and plural columns, each row including at least one word line connected to memory cells in the row, and each column including at least one bit line connected to memory cells in the column; wherein the memory cells store computational weight data for an in-memory computation operation; and an input/output circuit for each column. The input/output circuit comprises: a write circuit configured to write the computational weight data to memory cells in the memory array with a randomly selected polarity inversion; and a read circuit configured to read the computational weight data from memory cells in the memory array during execution of the in-memory computation operation and apply a polarity inversion to the read computational weight data when that read computational weight data was written to memory cells in the memory array with the randomly selected polarity inversion.

In an embodiment, a method for handling computational weight data for an in-memory computation operation, comprising: writing computational weight data to memory cells in a memory array with a randomly selected polarity inversion; reading the computational weight data from memory cells in the memory array during execution of the in-memory computation operation; and applying a polarity inversion to the read computational weight data when that read computational weight data was written to memory cells in the memory array with the randomly selected polarity inversion.

### BRIEF DESCRIPTION OF THE DRAWINGS

For a better understanding of the embodiments, reference will now be made by way of example only to the accompanying figures in which:

FIG. 1 is a schematic diagram of a circuit supporting both conventional memory access processing and digital in-memory computation processing;

FIG. 2 is a circuit diagram of a 6T static random access memory (SRAM) cell used in the circuit of FIG. 1;

FIG. 3 is a circuit diagram of an 8T SRAM cell used in the circuit of FIG. 1;

FIG. 4 shows a block diagram for an embodiment of a column I/O circuit for the memory circuit in FIG. 1; and

FIGS. 5A and 5B show block diagrams for implementations accounting for sparsity management to provide protection against side channel attack.

### DETAILED DESCRIPTION OF THE DRAWINGS

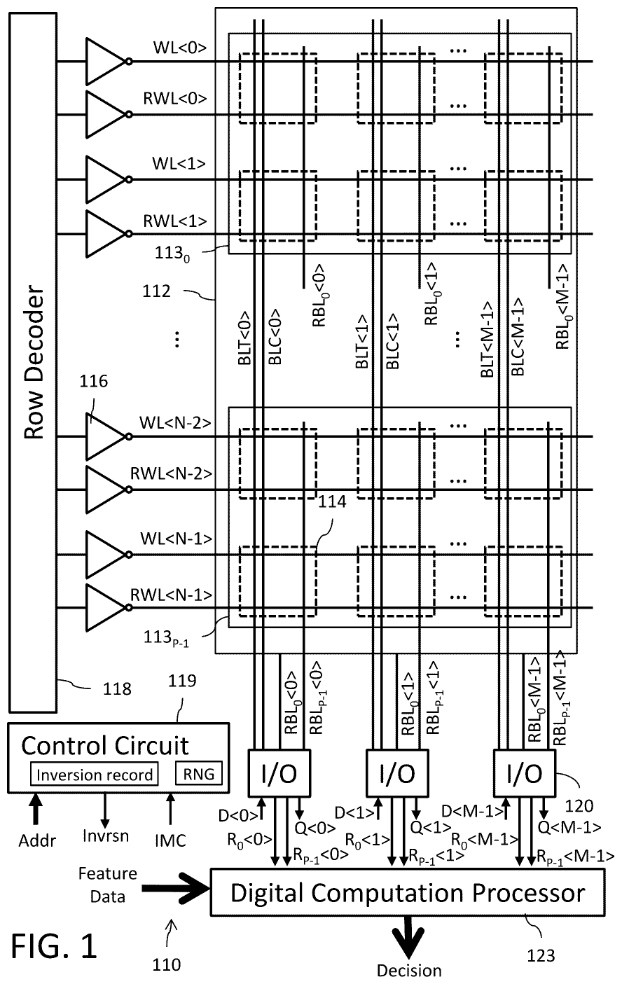

Reference is now made to FIG. 1 which shows a block diagram of a circuit 110 supporting both conventional memory access processing and digital in-memory computation processing. The circuit 110 is implemented using a memory circuit which includes a static random access memory (SRAM) array 112 formed by a plurality of SRAM memory cells 114 arranged in a matrix format having N rows and M columns. Each memory cell 114 is programmed to store a bit of data. In conventional memory access processing, the stored data in the memory array 112 can be any desired user data. In digital in-memory computation processing, the stored data in the memory array 112 comprises computational weight or kernel data for a digital in-memory compute operation. In this context, the digital in-memory compute operation is understood to be a form of a high dimensional Matrix Vector Multiplication (MVM) supporting multi-bit weights that are stored in multiple bit cells of the memory. The group of bit cells (in the case of a multibit weight) can be considered as a virtual synaptic element. Each bit of data stored in the memory array, whether user data or weight data, has either a logic “1” or a logic “0” value.

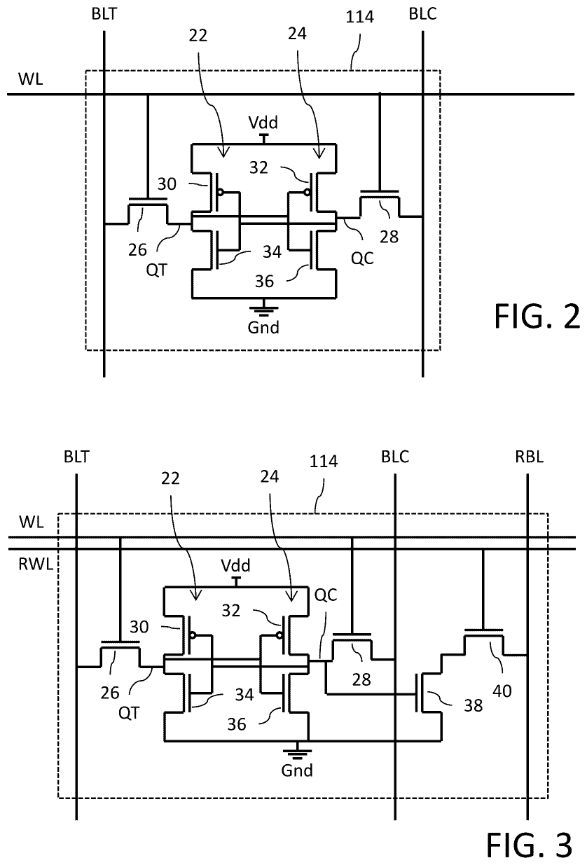

Each SRAM memory cell 114 may comprise a 6T-type memory cell as shown in FIG. 2. The cell 114 includes two cross-coupled CMOS inverters 22 and 24, each inverter including a series connected p-channel and n-channel MOSFET transistor pair. The inputs and outputs of the inverters 22 and 24 are coupled to form a latch circuit having a true data storage node QT and a complement data storage node QC which store complementary logic states of the stored data bit. The cell 14 further includes two transfer (passgate) transistors 26 and 28 whose gate terminals are driven by a word line WL. The source-drain path of transistor 26 is connected between the true data storage node QT and a node associated with a true bit line BLT. The source-drain path of transistor 28 is connected between the complement data storage node QC and a node associated with a complement bit line BLC. The source terminals of the p-channel transistors 30 and 32 in each inverter 22 and 24 are coupled to receive a high supply voltage (for example, Vdd) at a high supply node, while the source terminals of then-channel transistors 34 and 36 in each inverter 22 and 24 are coupled to receive a low supply voltage (for example, ground (Gnd) reference) at a low supply node.

Alternatively, each SRAM memory cell 114 may comprise an 8T-type memory cell as shown in FIG. 3. The cell 114 includes two cross-coupled CMOS inverters 22 and 24, each inverter including a series connected p-channel and n-channel MOSFET transistor pair. The inputs and outputs of the inverters 22 and 24 are coupled to form a latch circuit having a true data storage node QT and a complement data storage node QC which store complementary logic states of the stored data bit. The cell 14 further includes two transfer (passgate) transistors 26 and 28 whose gate terminals are driven by a word line WL. The source-drain path of transistor 26 is connected between the true data storage node QT and a node associated with a true bit line BLT. The source-drain path of transistor 28 is connected between the complement data storage node QC and a node associated with a complement bit line BLC. The source terminals of the p-channel transistors 30 and 32 in each inverter 22 and 24 are coupled to receive a high supply voltage (for example, Vdd) at a high supply node, while the source terminals of the n-channel transistors 34 and 36 in each inverter 22 and 24 are coupled to receive a low supply voltage (for example, ground (Gnd) reference) at a low supply node. A signal path between the read bit line RBL and the low supply voltage reference is formed by series coupled transistors 38 and 40. The gate terminal of the (read) transistor 38 is coupled to the complement storage node QC and the gate terminal of the (transfer) transistor 40 is coupled to receive the signal on the read word line RWL.

It will be understood that the circuit 110 may instead use a different type of memory cell, for example any form of a bit cell, storage element or synaptic element producing a deterministic readout arranged in an array. As a non-limiting example, consideration is made for the use of a non-volatile memory (NVM) cell such as, for example, magnetoresistive RA M (MRAM) cell, Flash memory cell, phase change memory (PCM) cell or resistive RAM (RRAM) cell). In the following discussion, focus is made on the implementation using an 8T-type SRAM cell 114, but this is done by way of a non-limiting example, understanding that any suitable memory element could be used (e.g., a binary (two level) storage element or an m-ary (multi-level) storage element).

Each cell 114 includes a word line WL, a pair of complementary bit lines BLT and BLC, a read word line RWL and a read bit line RBL. The SRAM memory cells in a common row of the matrix are connected to each other through a common word line WL and through a common read word line RWL. Each of the word lines (WL and/or RWL) is driven by a word line driver circuit 116 with a word line signal generated by a row decoder circuit 118 during read and write operations. The SRAM memory cells in a common column of the matrix across the whole array 112 are connected to each other through a common pair of complementary (write) bit lines BLT and BLC. The array 112 is segmented into P sub-arrays 113₀ to 113_{P-1}. Each sub-array 113 includes M columns and N/P rows of memory cells 114. The SRAM memory cells in a common column of each sub-array 113 are connected to each other through a local read bit line RBL.

The P local read bit lines RBL₀<x> to RBL_{P-1}<x> from the sub-arrays 113 for the column x in the array 112 are coupled, along with the common pair of complementary bit lines BLT<x> and BLC<x> for the column x in the array 112, to a column input/output (I/O) circuit 120(x). Here, x=0 to M−1. A data input port (D) of the column I/O circuit 120 receives input data (user or weight data) to be written to an SRAM memory cell 114 in the column through the pair of complementary bit lines BLT, BLC in response to assertion of a word line signal in a conventional memory access mode of operation. A data output port (Q) of the column I/O circuit 120 generates output data read from an SRAM memory cell 14 in the column through the read bit line RBL in response to assertion of a read word line signal in the conventional memory access mode of operation. Additionally, the column I/O circuit 120 further includes P sub-array data output ports R₀ to R_{P-1} to generate output data read from a memory cell 114 on the local read bit line RBL of the corresponding sub-array 113₀ to 113_{P-1}, respectively, in response to the simultaneous assertion of a plurality of read word line signals (one per sub-array 113) in a digital in-memory compute mode of operation. A digital computation processing circuit 123 performs digital computations on the output data from the sub-array data output ports R as a function of received feature data and generates a decision output for the digital in-memory compute operation. The processing circuit 123 can implement computation logic for the digital signal processing in a number of ways including: full support of Boolean operations (XOR, XNOR, NAND, NOR, etc.) and vector operations depending on system and application needs; accumulation pipeline operations where vector multiplication is supported within the memory; and matrix vector multiplication pipeline operations where output from the memory as one vector for the multiply and accumulate (MAC) function. It will be noted that the processing circuit 123 is an integral part of the digital in-memory computation circuit 110.

The computation logic for the digital signal processing performed by processing circuit 123 is closely integrated with the input/output circuits and the sub-array data output ports R₀ to R_{P-1} to support utilization of a wide (for example, P times) vector access. There are a number of figure of merit (FOM) benefits which accrue from this solution including: enabling multi-word access in a same cycle amortizes the common logic toggling power inside the SRAM when wide vector access occurs; the use of sub-arrays 113 can reduce bit line toggling power consumption (i.e., where P word lines are asserted in parallel to access P corresponding sub-arrays); support of both, with the opportunity to toggle between, the conventional memory access mode of operation and the digital in-memory compute mode of operation; and on/off current ratio on the same bitline improves which is a key concern when the circuitry is implemented using fully-depleted silicon-on-insulator (FDSOI) technology where forward body bias is aggressively used.

It will be noted that the circuit 110 presents a conventional SRAM interface through the data input ports D and the data output ports Q in accordance with the conventional memory access mode of operation. In response to an applied memory address (Addr), the circuit supports read (via data output ports Q) and write (via data input ports D) access to a single row of memory cells 114 in the array 112 by the selected assertion of a single word line WL or RWL. The circuit further presents a sub-array processing interface through the sub-array data output ports R₀ to R_{P-1} in accordance with the digital in-memory compute mode of operation.

In response to an applied computational address (Addr), the circuit supports simultaneous read (via data output ports R₀ to R_{P-1}) access to a single row of memory cells 114 in each of the sub-arrays 113₀ to 113_{P-1} by the simultaneous assertion of corresponding read word lines RWL. A single computational address can be decoded to select the plural word lines (one per sub-array 113) for assertion, or plural computational addresses can be decoded to select the plural word lines (one per sub-array 113) for assertion. The use plural sub-arrays 113 in this mode enables parallelism supporting very wide access for computation processing without sacrificing density. Advantageously, this digital in-memory compute mode of operation utilizes the resources of the conventional SRAM design with modified control, decoding and input/output circuits (as will be discussed herein in detail) to enable parallel access in the digital in-memory compute mode of operation with additional control to toggle between the conventional memory access mode of operation and the digital in-memory compute mode of operation as needed by the system application. This architecture brings parallelism with usage of the push rule bitcell thus enabling high density/compute density when configured for the in-memory compute mode of operation. Notwithstanding the foregoing, as noted above, usage of other bitcell types may instead be made.

A control circuit 119 controls mode operations of the circuitry within the circuit 110 responsive to the logic state of a control signal IMC. When the control signal IMC is in a first logic state (for example, logic low), the circuit 110 operates in accordance with the conventional memory access mode of operation (for writing data from data input port D to the memory array or reading data from the memory array to data output port Q at a memory address selected by the applied memory access address—Addr). Conversely, when the control signal IMC is in a second logic state (for example, logic high), the circuit 110 operates in accordance with the digital in-memory compute mode of operation (for reading weight data from the memory array to the sub-array data output ports R at multiple memory addresses selected by the applied computational address—Addr).

When the circuit 110 is operating in the conventional memory access mode of operation, the row decoder circuit 118 decodes a received memory access address (Addr), selectively actuates only one word line WL (during write) or one read word line RWL (during read) for the whole array 112 with a word line signal pulse to access a corresponding single one of the rows of memory cells 114. In write, logic states of the data at the input ports D are written by the column I/O circuits 120 through the pairs of complementary bit lines BLT, BLC to the single row of memory cells coupled to the accessed word line WL with an application of a randomly selected data polarity inversion. In read, the logic states of the data stored in the single row of memory cells coupled to the accessed word line WL are sensed from the read bit lines RBL by the column I/O circuits 120 for output at the data output ports Q with a data polarity inversion corresponding to the randomly selected data polarity inversion used when writing that data to the memory.

The foregoing may be better understood by reference to an example. Consider the operation to write the eight bit data word D=<00111101> to a memory access address Addr=A in the memory. The row decoder circuit 118 decodes the access address Addr=A and selectively actuates the word line WL corresponding to that address in memory with a word line signal pulse to access eight memory cells 114 in the corresponding row. In response to a first logic state of a data polarity inversion control signal Invrsn, the column I/O circuits 120 will apply the eight bits of the data word D=<00111101>, without any modification, through the pairs of complementary bit lines BLT, BLC for storage in the accessed eight memory cells 114. Conversely, in response to a second logic state of the data polarity inversion control signal Invrsn, the column I/O circuits 120 will invert the polarity of the eight bits of the data word D=<00111101> to generate an inverted polarity data word Dinv=<11000010> and apply the eight bits of the inverted polarity data word through the pairs of complementary bit lines BLT, BLC for storage in the accessed eight memory cells 114. Whether the data polarity inversion control signal Invrsn has the first logic state or second logic state is randomly selected by the control circuit 119 in response to the operation of a random number generator (RNG) circuit.

Now consider the operation to read the eight bit data word which is stored at the same address Addr=A from in the memory. The row decoder circuit 118 again decodes the memory access address Addr=A and selectively actuates the read word line RWL corresponding to that access address with a word line signal pulse to access eight memory cells 114 in the corresponding row. Because the address Addr=A is known by the control circuit 119 to be an address where randomized data polarity inversion was applied during the data write operation, the control circuit 119 sets the data polarity inversion control signal Invrsn to the second logic state, the column I/O circuits 120 sense the eight bits of the inverted polarity data word Dinv=<11000010> and apply an inversion of polarity to generate the eight bits of the data word D=<00111101> for output. Assuming for sake of complete explanation the situation where instead the address Addr=A was not known by the control circuit 119 to be an address where randomized data polarity inversion has been applied, the control circuit 119 would instead set the data polarity inversion control signal Invrsn to the first logic state, and the column I/O circuits 120 would then sense the bits of the data word D=<00111101> for output.

In an embodiment, an inversion record, for example in the form of a look-up table, is kept by the control circuit 119 of the addresses in memory to which the randomized data polarity inversion has been selectively applied for storage of the computational weight data. This inversion record can be consulted by the control circuit 119 to identify in connection with a memory access operation whether a randomized data polarity inversion has been applied in order to properly set the logic state of the data polarity inversion control signal Invrsn.

In another embodiment, it will be noted that the RNG could utilize a pseudorandom binary sequence (PRBS) polynomial for generating the random number RN from a seed value. Because this polynomial is primitive but known, multiple instances of the RNG could be used, synchronized with each other and factoring in latency. With such an implementation, there is no need for using a look-up table to store the data for the inversion record. The generation of a corresponding RN for each of the write operation and read operation from the same seed can control the proper (and matching) setting of the logic state of the data polarity inversion control signal Invrsn during both the write operation and the subsequent read operation at a common address in memory.

It will be noted that reference to a random number herein would encompass a true random number or a pseudorandom number, where such a number has any desired level of precision.

When the circuit 110 is operating in the digital in-memory compute mode of operation, the row decoder circuit 118 decodes a received computation address (Addr), selectively (and simultaneously) actuates one read word line RWL in each sub-array 113 in the memory array 112 with a word line signal pulse to access a corresponding row of memory cells 114 in each sub-array 113. The logic states of the weight data stored in the row of memory cells coupled to the accessed read word line RWL in each sub-array 113 are passed from the read bit lines RBL₀<x> to RBL_{P-1}<x> to the column I/O circuit 120 for output at the corresponding sub-array data output ports R₀ to R_{P-1} with a data polarity inversion corresponding to the randomly selected data polarity inversion used when writing that data to the memory.

The foregoing may be better understood by reference to an example. Consider here an in-memory computation operation specifying the computation address Addr=B. The row decoder circuit 118 decodes the computation address Addr=B and selectively actuates one read word line RWL in each sub-array 113 with a word line signal pulse. One of the actuated read word lines RWL is associated with the address Addr=A and the eight memory cells 114 noted above where the eight bit data word D=<00111101> was written with the randomized data polarity inversion as the inverted polarity data word Dinv=<11000010>. As noted above, this can be recognized by the control circuit 119 using the data stored in the inversion record, or through the PRBS generation using the common seed and factoring in latency as noted above, and the data polarity inversion control signal Invrsn is set to the second logic state. The column I/O circuits 120 would sense the bits of the inverted polarity data from the accessed memory cells 114 and selectively apply an inversion of polarity as required to generate the bits of data output at the corresponding sub-array data output ports R₀ to R_{P-1} with the correct polarity values.

The application of a randomized data polarity inversion on a word-by-word basis as indicated by the example described above will be understood to be just one way of implementation. The randomized data polarity inversion may instead be applied on bit-by-bit basis. Alternatively, the randomized data polarity inversion may instead be applied on a row-by-row basis, or on a column-by-column basis. Still further, the randomized data polarity inversion may instead be applied for any desired sub-set of memory cells within the array or sub-array. In each case, the record of application of the randomized data polarity inversion is saved by the data stored in the inversion record, or recognized through the PRBS generation using the common seed and factoring in latency as noted above, and used to properly recover the true logic state in either the conventional mode read operation or the in-memory compute operation.

It will be noted that each sub-array 113 output can be considered as one subtensor/tensor for processing operations. Additionally, multiple sub-arrays 113 outputs can be grouped as a larger tensor. The grouping of sub-array outputs can be made across columns, across rows, or both. Such processing is supported through the configuration and operation of the processing circuit 123. Again, the randomized data polarity inversion may be applied with respect to a given subtensor/tensor or any selected grouping of sub-array outputs across columns, across rows, or both. Details of the selective application on the data polarity inversion are stored in the inversion record, or recognized through the PRBS generation using the common seed and factoring in latency as noted above, and used to selectively apply polarity inversion to each bit as needed. The goal of the randomized data polarity inversion is to assist in removing the static property of a weight stationary approach to storage of the computational weight data in the memory array by sacrificing a portion of weight sparsity in order to eliminate static weight sparsity based power consumption profiles which can be exploited in a side channel attack.

It will be noted that a high degree of granular control can be exercised over the data polarity inversion by the use of unique polarity inversion control signals Invrsn. In such a case, the polarity inversion control signals Invrsn may be considered as a multi-bit signal with each individual bit be assigned to control a specific polarity inversion operation, or where a decoding of the multi-bit polarity inversion control signal Invrsn generates individual bits that are assigned to control a specific polarity inversion operation.

The architecture shown in FIG. 1 presents a number of advantages for digital in-memory computation including: very wide vector access is enabled for supporting high dimensional tensor processing for an artificial neural network (ANN); hyper dimensional computing for artificial intelligence (AI) training and inference workloads is also supported; the computation is deterministic with a wide range of weight data and feature data precisions and number formats permitted for neural network applications (noting that this is a significant differentiation versus analog in-memory computation—which is limited to simplified signed/unsigned integer formats); and the solution is extendable to incorporate additional stochastic compute modes to gain area and power efficiency.

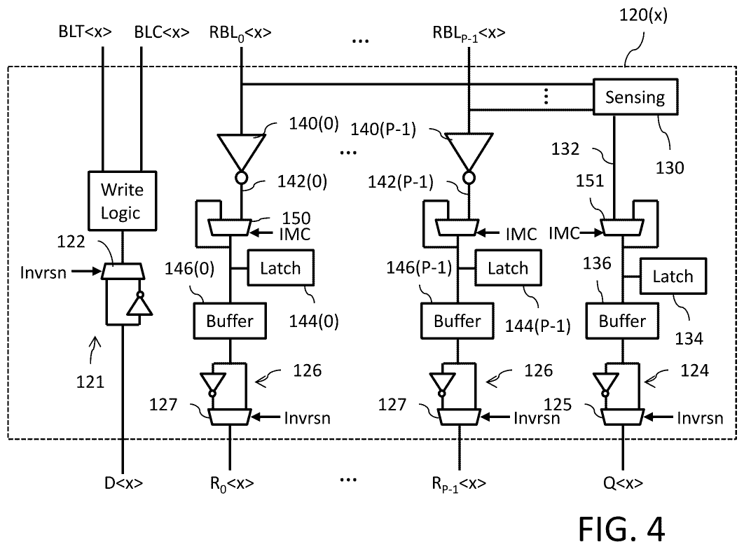

A block diagram of an embodiment for the column I/O circuit 120 is shown in FIG. 4. The column I/O circuit 120(x) is coupled to the pair of complementary bit lines BLT<x>, BLC<x> for the column x in the array 112. The polarity of the bit at the data input port D<x> is selectively inverted by polarity inversion circuit 121 and coupled through a write logic circuit to drive the pair of complementary bit lines. The polarity inversion circuit 121 includes a multiplexer 122 having a first input coupled to receive the bit at the data input port D<x> and a second input coupled to receive the logical inversion of the bit at the data input port D<x>. The selection control input of the multiplexer 122 receives a bit of the data polarity inversion control signal Invrsn generated by the control circuit 119. In response to the first logic state of that bit of the data polarity inversion control signal Invrsn, the multiplexer 122 selects the first input and passes the bit at the data input port D<x> (i.e., with no polarity inversion) to the write logic circuit to be written into the selected memory cell 114. In response to the second logic state of that bit of the data polarity inversion control signal Invrsn, the multiplexer 122 selects the second input and passes the logically inverted bit at the data input port D<x> (i.e., with polarity inversion) to the write logic circuit to be written into the selected memory cell 114.

The column I/O circuit 120(x) is also coupled to the P local read bit lines RBL₀<x> to RBL_{P-1}<x> from the sub-arrays 113 for the column x in the array 112 through a read logic circuit. A sensing circuit 130 of the read logic circuit is coupled to receive the data on the P local read bit lines RBL₀<x> to RBL_{P-1<x> and generate a sensed data bit on signal line 132. As an example, the sensing circuit 130 may comprise a logic NAND gate. The sensed data bit is applied to the first input of a multiplexer circuit 151 whose select input receives the control signal IMC. The second input of the multiplexer circuit 151 is coupled to the output of the multiplexer circuit 151. When the control signal IMC is in the first logic state (for example, logic low—when the circuit 110 is operating in accordance with the conventional memory access mode of operation), the multiplexer circuit 151 selects the data on signal line 132. Conversely, when the control signal IMC is in the second logic state (for example, logic high-when the circuit 110 is operating in accordance with the digital in-memory compute mode of operation), the multiplexer circuit 151 selects the data at the output of the multiplexer circuit 151 (which has been latched by latch circuit 134). The latched data at the output of multiplexer circuit 151 is buffered by buffer circuit 136. The polarity of the bit at the output of the buffer circuit 136 is selectively inverted by polarity inversion circuit 124 for output at the data output port Q<x>. The polarity inversion circuit 124 includes a multiplexer 125 having a first input coupled to receive the buffered bit and a second input coupled to receive the logical inversion of the buffered bit. The selection control input of the multiplexer 125 receives a bit of the data polarity inversion control signal Invrsn generated by the control circuit 119. In response to the first logic state of that bit of the data polarity inversion control signal Invrsn, the multiplexer 125 selects the first input and passes the buffered bit (i.e., with no polarity inversion) to the data output port Q<x>. In response to the second logic state of that bit of the data polarity inversion control signal Invrsn, the multiplexer 125 selects the second input and passes the logically inverted buffered bit (i.e., with polarity inversion) to the data output port Q<x>.}

A sensing circuit 140(y) of the read logic circuit is coupled to receive the data on the local read bit line RBL_{y}<x> and generate a sensed data bit on signal line 142(y). H ere, y=0 to P−1. A s an example, each sensing circuit 140 may comprise a logic NOT gate. The sensed data bit is applied to the second input of a multiplexer circuit 150 whose select input receives the control signal IMC. The first input of the multiplexer circuit 150 is coupled to the output of the multiplexer circuit 150. When the control signal IMC is in the first logic state (for example, logic low—when the circuit 110 is operating in accordance with the conventional memory access mode of operation), the multiplexer circuit 150 selects the data at the output of the multiplexer circuit 150 (which has been latched by latch circuit 144). Conversely, when the control signal IMC is in the second logic state (for example, logic high—when the circuit 110 is operating in accordance with the digital in-memory compute mode of operation), the multiplexer circuit 150 selects the data on signal line 142. The latched data at the output of multiplexer circuit 150 is buffered by buffer circuit 146(y). The polarity of the bit at the output of the buffer circuit 146 is selectively inverted by polarity inversion circuit 126 for output at the sub-array data output port R_{y}<x>. The polarity inversion circuit 126 includes a multiplexer 127 having a first input coupled to receive the buffered bit and a second input coupled to receive the logical inversion of the buffered bit. The selection control input of the multiplexer 127 receives a bit of the data polarity inversion control signal Invrsn generated by the control circuit 119. In response to that bit of the first logic state of the data polarity inversion control signal Invrsn, the multiplexer 127 selects the first input and passes the buffered bit (i.e., with no polarity inversion) at the sub-array data output port R_{y}<x>. In response to the second logic state of that bit of the data polarity inversion control signal Invrsn, the multiplexer 127 selects the second input and passes the logically inverted buffered bit (i.e., with polarity inversion) at the sub-array data output port R_{y}<x>.

It will be recognized that the operation described herein for randomized polarity inversion of the computational weight data is being implemented in a manner which presents a tradeoff between data sparsity (i.e., the emphasis on storing logic 1 data values in the memory) and energy efficiency in order to provide randomized weight inversions in connection with encrypting the computational weight data and providing a measure of protection that makes it more difficult for a power-based side channel attack to succeed in discerning the stored computational weight data.

It will be noted as well that the decision as to whether the randomized polarity inversion is to be applied to certain computational weight data can be made dependent on the sparsity of that computational weight data to be stored. Only in situations where the sparsity of the certain computational weight data exceeds a sparsity threshold level is that computational weight data even considered for randomized polarity inversion. Consider, for example, the eight bit data word D=<00111101> used in the example discussed above which includes five logic “1” bits and 3 logic “0” bits, and thus has a sparsity of ⅝ (number of logic “1” bits divided by total number of bits). The sparsity of this data word exceeds, for example, a sparsity threshold level of 0.5, and thus would be permitted to have a randomized polarity inversion applied (i.e., the polarity inversion would be selectively applied in this case dependent on the random logic state of the inversion control signal). Conversely, an eight bit data word D=<10101000> with three logic “1” bits and 5 logic “0” bits, and a sparsity value of ⅜ would not meet or exceed the example sparsity threshold level of 0.5, and thus would not be permitted for application of a randomized polarity inversion (i.e., no polarity inversion would occur even if the random logic state of the inversion control signal would otherwise have indicated polarity inversion should occur). The evaluation of the sparsity of the computational weight data to written to the array can be compared to the D=<00111101> can be performed by control circuit 119 (through a parallel input of the D<x> values) or by an external circuit which would provide sparsity information to the control circuit.

The foregoing example which illustrates granularity for sparsity evaluation at the word level is just one possible implementation. The sparsity evaluation can be made based on the data to be stored within any selected part of the array. For example, with respect to data stored in a row (or column), or based on the data stored in a segment of the array such as with the P sub-arrays 113₀ to 113_{P-1}.

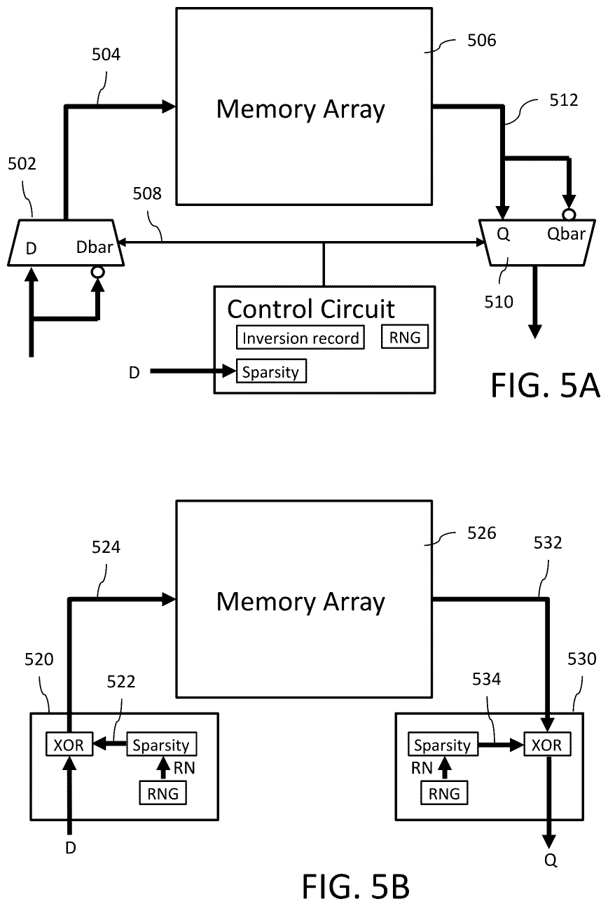

As an example implementation of the sparsity evaluation, consider FIG. 5A. In FIG. 5A, multiplexer 502 which receives the input data D and the logical inversion D bar thereof for the purpose of writing 504 data into the memory 506 receives a selection input signal 508. The selection input signal 508 is generated by the control circuit responsive to both the generated random number RN and an evaluation of the sparsity of the input data D in comparison to the sparsity threshold level to selectively apply the polarity inversion dependent on data sparsity considerations. Multiplexer 510 which receives the output data Q read 512 from the memory 506 and the logical inversion Q bar thereof also receives the selection input signal 508 in order to correctly apply the polarity inversion dependent on data sparsity.

As a further example implementation of the foregoing, consider FIG. 5B. In FIG. 5B, a write circuit 520 receives the input data D which is logically exclusive-ORed with a write control signal 522 to then be written 524 into the memory 526. The control signal 522 is a random vector that meets the sparsity threshold. The random number generator RNG for the write circuit generates the random number RN based on a seed value. The control signal 522 is generated based on the random number and a sparsity threshold. It w ill be noted, for example, that the control signal 522 can have a specific value for each of the P sub-arrays 113₀ to 113_{P-1}. Alternatively, there can be a specific value dependent on any selected segmentation of the memory space of the array. A read circuit 530 receives the data read 532 from the memory 526 which is logically exclusive-ORed with a read control signal 534 to generate the output data Q. The random number generator RNG for the read circuit generates the random number RN based on the same seed value in response to application of the same sparsity threshold.

It will be noted that an advantage of the foregoing, particularly in the context of FIG. 5B, is that similar power patterns are presented across operations in the P sub-arrays 113₀ to 113_{P-1}. This makes it very difficult to use a side channel attack to discern the stored computational weight data.

United States Patent Application Publication No. 2024/0071439 is incorporated herein by reference.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. A circuit, comprising:
a memory array including a plurality of memory cells arranged in a matrix with plural rows and plural columns, each row including at least one word line connected to memory cells in the row, and each column including at least one bit line connected to memory cells in the column;
wherein the memory cells store computational weight data for an in-memory computation operation; and
an input/output circuit for each column comprising:
a write circuit configured to write the computational weight data to memory cells in the memory array with a randomly selected polarity inversion; and
a read circuit configured to read the computational weight data from memory cells in the memory array during execution of the in-memory computation operation and apply a polarity inversion to the read computational weight data when that read computational weight data was written to memory cells in the memory array with the randomly selected polarity inversion.

2. The circuit of claim 1, wherein the randomly selected polarity inversion of the computational weight data during write is controlled by a control signal having a randomly selected logic state.

3. The circuit of claim 2, wherein the control signal is generated in response to a random number generator circuit.

4. The circuit of claim 1, further comprising a control circuit configured to generate a control signal having a randomly selected one of a first logic state and second logic state, said first logic state causing the write circuit to write the computational weight data without polarity inversion and said second logic state causing the write circuit to write the computational weight data with polarity inversion.

5. The circuit of claim 4, wherein the control circuit is further configured to permit the second logic state only when a sparsity of the computational weight data to be written to the memory array meets a sparsity threshold.

6. The circuit of claim 4, further comprising:
a word line drive circuit for each row having an output configured to drive the word line of the row; and
a row decoder circuit configured to actuate at least one of the word line drive circuits in response to a decoded access address when writing computational weight data to memory cells in the memory array;
wherein the control circuit further comprises an inversion record that stores addresses in the memory array where computational weight data with polarity inversion have been stored.

7. The circuit of claim 6, wherein the row decoder circuit further actuates one or more word line drive circuits in response to a decoded computation address during execution of the in-memory computation operation, and wherein the read circuit applies the polarity inversion when the computational weight data is read from the memory array at one of the addresses stored in the inversion record.

8. The circuit of claim 1, wherein the input/output circuit is configured to apply the polarity inversion by exclusively-ORing data with a control signal derived from a random number and a sparsity threshold for the memory.

9. The circuit of claim 8, wherein the random number is generated in both write to and write from the memory cells in the memory array in response to application of a same seed value.

10. The circuit of claim 1, wherein the input/output circuit is configured to applying a same seed value for random number generation to control the randomly selected polarity inversion in both write to and write from the memory cells in the memory array.

11. The circuit of claim 1, further comprising a processing circuit configured to receive feature data for the in-memory computation and perform a computational operation as a function of the feature data and data generated by the input/output circuits from the read computational weight data.

12. The circuit of claim 1, wherein each memory cell is a static random access memory (SRAM) cell or other logic bitcell.

13. The circuit of claim 12, wherein the SRAM cell is one of a 6T-type cell or an 8T-type cell.

14. The circuit of claim 1, wherein the in-memory computation operation is a digital in-memory computation.

15. A method for handling computational weight data for an in-memory computation operation, comprising:
writing computational weight data to memory cells in a memory array with a randomly selected polarity inversion;
reading the computational weight data from memory cells in the memory array during execution of the in-memory computation operation; and
applying a polarity inversion to the read computational weight data when that read computational weight data was written to memory cells in the memory array with the randomly selected polarity inversion.

16. The method of claim 15, wherein writing comprises applying polarity inversion to the computational weight data during write in response to a control signal having a randomly selected logic state.

17. The method of claim 16, further comprising using a random number generator circuit to generate the control signal.

18. The method of claim 16, further comprising permitting application of the polarity inversion only when a sparsity of the computational weight data to be written to the memory array meets a sparsity threshold.

19. The method of claim 16, further comprising storing in an inversion record addresses in the memory array where computational weight data with polarity inversion have been stored.

20. The method of claim 19, wherein applying the polarity inversion comprises applying the polarity inversion when the computational weight data is read from the memory array atone of the addresses stored in the inversion record.

21. The method of claim 16, further comprising applying the polarity inversion by exclusively-ORing the data with a control signal derived from a random number and a sparsity threshold for the memory.

22. The method of claim 21, further comprising applying a same seed value for generating the random number in both write to and write from the memory cells in the memory array.

23. The method of claim 16, further comprising applying a same seed value for random number generation to control the randomly selected polarity inversion in both write to and write from the memory cells in the memory array.
